(19) United States
(12) Patent Application Publication
(10) Pub. No.: US 2024/0266470 A1
(43) Pub. Date: Aug. 8, 2024

(54) LIGHT-EMITTING DEVICE, LIGHT-EMITTING MODULE AND PREPARATION METHOD THEREOF

(71) Applicants: BOE MLED Technology Co., Ltd., Beijing (CN); BOE Technology Group Co., Ltd., Beijing (CN)

(72) Inventors: Zhijun XIONG, Beijing (CN); Junjie MA, Beijing (CN); Yuanda LU, Beijing (CN); Jiawei ZHAO, Beijing (CN); Shanwei YANG, Beijing (CN); Yuanhao SUN, Beijing (CN); Xueqiao LI, Beijing (CN)

(21) Appl. No.: 18/279,310

(22) PCT Filed: Oct. 29, 2021
(86) PCT No.: PCT/CN2021/127553

§ 371 Date: Aug. 29, 2023

(51) Int. Cl. H01L 33/38; H01L 23/00; H01L 25/075

(52) U.S. Cl. CPC H01L 33/38; H01L 24/29; H01L 25/0753; H01L 2224/29019; H01L 2224/29021; H01L 2224/29111; H01L 2224/29194; H01L 2224/2957; H01L 2924/0132; H01L 2924/0133

(57) ABSTRACT

The present disclosure provides a light-emitting device, a light-emitting module and a preparation method thereof. The light-emitting device includes: a light-emitting structure; an electrode structure provided on the light-emitting structure; and a die-bonding structure, at least a portion of which covers a surface of the electrode structure facing away from the light-emitting structure, where the die-bonding structure includes a doping material for inhibiting generation of an intermetallic compound. The present disclosure is capable of improving the die-bonding rework yield and reducing the risk of failure of a display module.

### TECHNICAL FIELD

The present disclosure relates to the field of display technology, and in particular to a light-emitting device, a light-emitting module and a preparation method thereof.

### BACKGROUND

With the improvement of people's living standards, light-emitting modules have attracted more and more attention. The light-emitting module includes a substrate and a light-emitting device. The light-emitting device may be soldered to the substrate through a die-bonding process. However, the light-emitting module is prone to failure.

### SUMMARY

The present disclosure aims to provide a light-emitting device, a light-emitting module and a preparation method thereof, which can reduce the risk of failure of a display module.

According to an aspect of the present disclosure, there is provided a light-emitting device including:
a light-emitting structure;
an electrode structure provided on the light-emitting structure; and
a die-bonding structure, at least a portion of which covers a surface of the electrode structure facing away from the light-emitting structure, where the die-bonding structure includes a doping material for inhibiting generation of an intermetallic compound.

Further, the die-bonding structure includes:
a solder layer covering the surface of the electrode structure facing away from the light-emitting structure, the doping material being doped in the solder layer.

Further, the doping material includes at least one of nickel, ferric oxide, silicon dioxide, titanium dioxide, or zirconium dioxide.

Further, a solder in the solder layer includes at least one of tin, tin-silver alloy, tin-silver-copper alloy, indium-tin alloy, or tin-copper alloy.

Further, the electrode structure includes:
an electrode layer provided on the light-emitting structure; and
a barrier layer provided on a side of the electrode layer facing away from the light-emitting structure, the barrier layer being made of a conductive material.

Further, the barrier layer is made of at least one of nickel, platinum, or gold.

Further, the light-emitting device further includes an insulation layer covering the electrode layer, the insulation layer being provided with an opening exposing the electrode layer, and the electrode structure further includes:
a conductive bridging layer provided on a surface of the insulation layer facing away from the light-emitting structure, extending into the opening and being in contact with the electrode layer, the barrier layer being provided on a surface of the conductive bridging layer facing away from the light-emitting structure.

Further, the light-emitting device further includes an insulation layer covering the electrode layer, the insulation layer being provided with an opening exposing the electrode layer, and the electrode structure further includes:
a conductive filler filling the opening and being in contact with the electrode layer; and
a conductive bridging layer provided on a surface of the insulation layer facing away from the light-emitting structure and being in contact with a surface of the conductive filler facing away from the light-emitting structure, the barrier layer being provided on a surface of the conductive bridging layer facing away from the light-emitting structure.

Further, the surface of the conductive filler facing away from the light-emitting structure is flush with the surface of the insulation layer facing away from the light-emitting structure; or
the surface of the conductive filler facing away from the light-emitting structure is lower than the surface of the insulation layer facing away from the light-emitting structure.

Further, the die-bonding structure includes:
a solder layer covering a surface of the electrode structure facing away from the light-emitting structure; and
a liquid film covering the solder layer and made of a soldering flux, the doping material being doped in the liquid film.

Further, the electrode structure includes two electrode structures, the solder layer includes two solder layers, and the liquid film includes two liquid films arranged at intervals; the two solder layers are arranged on surfaces of the two electrode structures in a one-to-one correspondence, and the two liquid films cover the two solder layers in a one-to-one correspondence; and the doping material includes at least one of nickel, ferric oxide, silicon dioxide, titanium dioxide, or zirconium dioxide.

Further, the electrode structure includes two electrode structures, the solder layer includes two solder layers, and the liquid film includes one liquid film; the two solder layers are arranged on surfaces of the two electrode structures in a one-to-one correspondence, and the liquid film covers the two solder layers; and the doping material includes an insulating material.

Further, the doping material includes at least one of silicon dioxide, titanium dioxide, or zirconium dioxide.

According to an aspect of the present disclosure, there is provided a light-emitting module including:
a substrate provided with at least one group of pads; and
the above light-emitting device soldered to the pads on the substrate through the die-bonding structure.

According to an aspect of the present disclosure, there is provided a preparation method of a light-emitting module, including:
providing a substrate, which is provided with at least one group of pads; and
soldering the above light-emitting device to the pads on the substrate through the die-bonding structure with a heat soldering process.

Further, the heat soldering process includes a hot-pressure soldering process, a reflow soldering process, or a laser soldering process.

With the light-emitting device, the light-emitting module and the preparation method thereof according to the present disclosure, at least a portion of a die-bonding structure covers a surface of an electrode structure facing away from a light-emitting structure. Since a doping material in the die-bonding structure can be used for inhibiting generation of an intermetallic compound, a thickness of an intermetallic compound layer formed during a die-bonding process can be reduced, which can prevent peeling of pads on a substrate and avoid damage to the light-emitting module, thereby improving the die-bonding rework yield and reducing the risk of failure of a display module.

### BRIEF DESCRIPTION OF DRAWINGS

FIG. 1 is a schematic diagram illustrating a die-bonding process in the related art.

FIG. 2 is a schematic diagram illustrating the die-bonding process shown in FIG. 1 after completion.

FIG. 3 is a schematic diagram illustrating a structure shown in FIG. 2 after rework.

FIG. 4 is a schematic diagram illustrating a light-emitting device according to an embodiment of the present disclosure.

FIG. 5 is a schematic diagram illustrating a light-emitting device according to another embodiment of the present disclosure.

FIG. 6 is a schematic diagram illustrating a light-emitting device according to yet another embodiment of the present disclosure.

FIG. 7 is a schematic diagram illustrating a light-emitting module according to an embodiment of the present disclosure.

FIG. 8 is a schematic diagram illustrating the light-emitting device shown in FIG. 4 before a liquid film is formed.

FIG. 9 is an electron micrograph of an intermetallic compound.

FIG. 10 is an electron micrograph of another intermetallic compound.

FIG. 11 is an electron micrograph of yet another intermetallic compound.

### DESCRIPTION OF REFERENCE NUMERALS

1. light-emitting structure; 100. base substrate; 101. epitaxial structure; 1011. first conductivity type semiconductor layer; 1012. light-emitting layer; 1013. second conductivity type semiconductor layer; 2. electrode structure; 201. electrode layer; 202. conductive bridging layer; 203. barrier layer; 204. conductive filler; 3. die-bonding structure; 301. solder layer; 302. liquid film; 4. insulation layer; 5. doping material; 6. substrate; 7. pad; 8. solder paste; 9. intermetallic compound layer; 10. soldering layer.

### DETAILED DESCRIPTION

Reference will now be made in detail to exemplary embodiments, examples of which are illustrated in the accompanying drawings. When the following description refers to the drawings, the same numerals in different drawings indicate the same or similar elements, unless otherwise indicated. Embodiments described in the following exemplary embodiments are not intended to represent all embodiments consistent with the present disclosure. Rather, they are merely examples of apparatuses consistent with some aspects of the present disclosure as detailed in the appended claims.

Terminology used in the present disclosure is for the purpose of describing particular embodiments only, and is not intended to be limiting of the present disclosure. Unless otherwise defined, technical or scientific terms used in the present disclosure shall have their ordinary meanings as understood by those ordinary skilled in the art to which the present disclosure pertains. Terms “first,” “second,” and the like as used in the specification and claims of the present disclosure are not intended to denote any order, quantity, or importance, but are merely used to distinguish one component from another. Similarly, words “a” or “an” and the like are not intended to denote a limitation in quantity, but rather denote the presence of at least one. “A plurality of” or “several” means two or more. Unless otherwise indicated, words “front,” “rear,” “lower,” and/or “upper” and the like are used for convenience of description only, and are not limited to a position or a spatial orientation. Words “comprise” or “include” and the like are intended to mean that elements or items appearing before “comprise” or “include” encompass elements or items listed after “comprise” or “include” and equivalents thereof, without excluding other elements or items. Words “connect” or “couple” and the like are not limited to physical or mechanical connections, but may include electrical connections, whether direct or indirect. As used in the specification and the appended claims of the present disclosure, the singular forms of “a,” “an,” “the,” and “said” are intended to include plural forms as well, unless the context clearly dictates otherwise. It should also be understood that the term “and/or” as used herein refers to and encompasses any or all possible combinations of one or more of the associated listed items.

An intermetallic compound (IMC) is a compound composed of two or more metal components in proportion, which has the basic properties of a metal and a long-range ordered crystal structure distinct from its components. Simply speaking, an intermetallic compound is a compound composed of metal elements chemically bonded together in various atomic weight ratios.

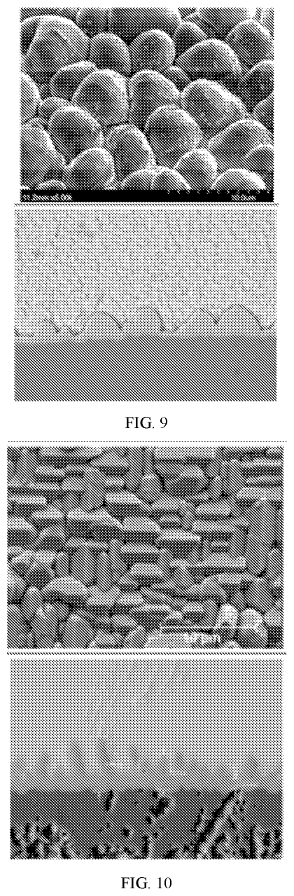

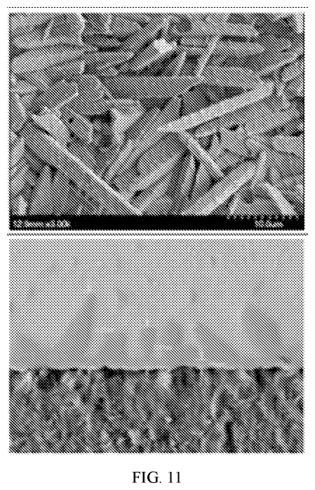

During a die-bonding process, the key to evaluating a good soldering is whether a benign metal compound is generated or not. The inventors of the present disclosure found through research that a film composed of a benign metal compound has a continuous and uniform surface in a scallop shape as shown in FIG. 9. With an increase in soldering temperature and time, the intermetallic compound may be grown excessively, and the surface of the film may be changed from the initial scallop shape to a ridge shape as shown in FIG. 10, and eventually to a malignant prism shape as shown in FIG. 11. Accordingly, an internal stress the intermetallic compound is subjected to may be increased, resulting in weakening of mechanical strength, reducing the soldering quality, and in turn causing phenomena such as poor soldering and dead lamp.

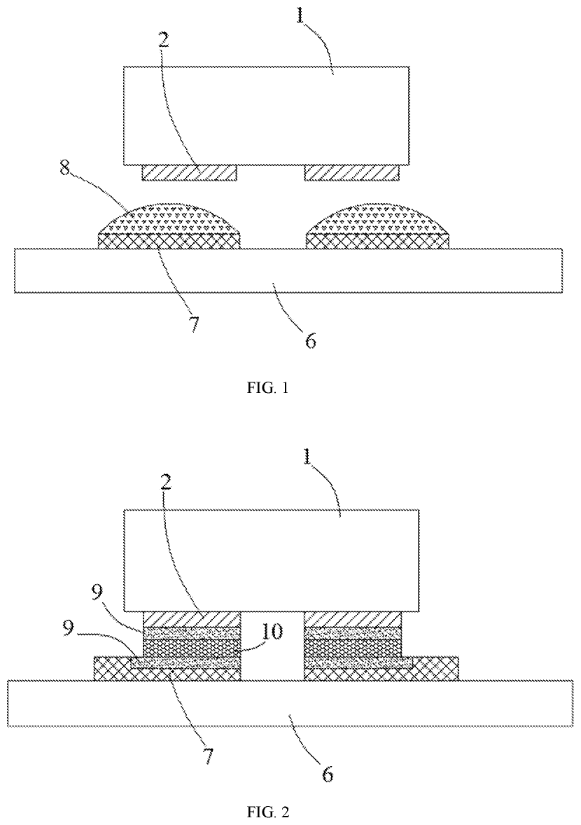

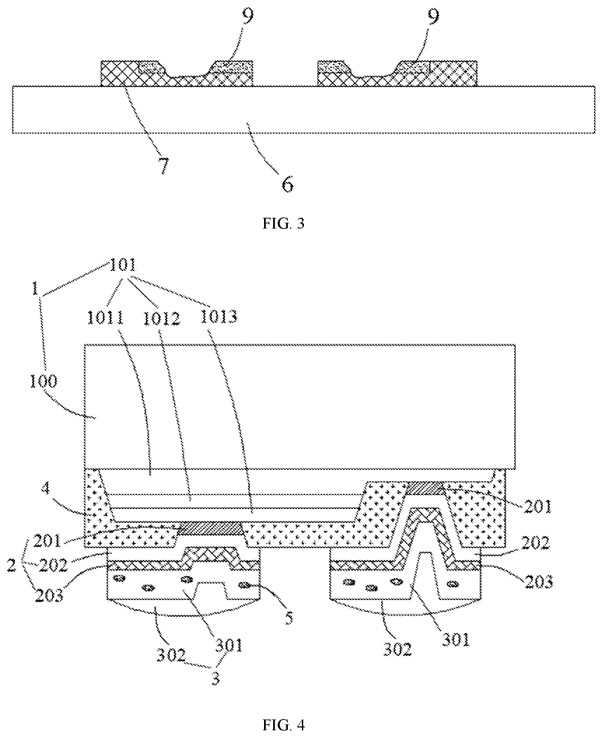

As shown in FIG. 1 and FIG. 2, a light-emitting module includes a substrate 6 and a light-emitting device soldered to the substrate 6. In FIG. 2, an intermetallic compound layer 9 is provided between an electrode structure 2 and a soldering layer 10, and between pads 7 and the soldering layer 10. When the light-emitting module is a Mini LED light-emitting module, tens of thousands to hundreds of thousands of light-emitting devices need to be die-bonded on a single substrate 6. In order to ensure a 100% yield, it is inevitable to perform rework. Heat input generated during the rework may cause excessive growth of the intermetallic compound, further increasing a thickness of the intermetallic compound layer 9. Moreover, since a melting point of the intermetallic compound is higher than that of the soldering layer 10, peeling of the pads 7 is prone to occur after the rework, as shown in FIG. 3.

Embodiments of the present disclosure provide a light-emitting device. The light-emitting device may be a Micro light-emitting diode (Micro LED); however, the light-emitting device may also be a Mini light-emitting diode (Mini LED), and the present disclosure is not limited thereto. As shown in FIGS. 4-6, the light-emitting device may include a light-emitting structure 1, an electrode structure 2, and a die-bonding structure 3.

The electrode structure 2 may be provided on the light-emitting structure 1. At least a portion of the die-bonding structure 3 covers a surface of the electrode structure 2 facing away from the light-emitting structure 1. The die-bonding structure 3 includes a doping material 5. The doping material 5 is used to inhibit generation of an intermetallic compound.

With the light-emitting device according to the embodiments of the present disclosure, at least a portion of a die-bonding structure 3 covers a surface of an electrode structure 2 facing away from a light-emitting structure 1. Since a doping material 5 in the die-bonding structure 3 can be used for inhibiting generation of an intermetallic compound, a thickness of an intermetallic compound layer 9 formed during a die-bonding process can be reduced, which can prevent peeling of pads 7 on a substrate 6 and avoid damage to a light-emitting module, thereby improving the die-bonding rework yield and reducing the risk of failure of a display module. The doping material 5 contains inactive ions. The inactive ions may not react with the solder in the die-bonding structure 3 to generate an intermetallic compound, and can be regarded as second-phase ions, which play a role in inhibiting the growth of the intermetallic compound, change the microstructure of the solder alloy formed during the die-bonding process, and improve the mechanical properties of the solder alloy.

Parts of the light-emitting device according to the embodiments of the present disclosure will be described in detail below.

As shown in FIG. 4, the light-emitting structure 1 may be an LED chip, but the present disclosure is not limited thereto. The LED chip may include a base substrate 100 and an epitaxial structure 101. The base substrate 100 may be one of a sapphire base substrate 100, a silicon carbide base substrate 100, a silicon nitride base substrate 100, and a silicon base substrate 100, which is not limited in the embodiments of the present disclosure. The epitaxial structure 101 may be disposed on a side of the base substrate 100. The epitaxial structure 101 may include a first conductivity type semiconductor layer 1011, a light-emitting layer 1012, and a second conductivity type semiconductor layer 1013. The first conductivity type semiconductor layer 1011 may be disposed on a side of the base substrate 100, the light-emitting layer 1012 may be disposed on a side of the first conductivity type semiconductor layer 1011 facing away from the base substrate 100, and the second conductivity type semiconductor layer 1013 may be disposed on a side of the light-emitting layer 1012 facing away from the base substrate 100. The first conductivity type is different from the second conductivity type. The first conductivity type semiconductor layer 1011 may be a p-type semiconductor layer, and the second conductivity type semiconductor layer 1013 may be an n-type semiconductor layer, which is not particularly limited in the embodiments of the present disclosure. The light-emitting layer 1012 may have one of a single quantum well structure, a multiple quantum well (MQW) structure, a quantum wire structure, and a quantum dot structure. For example, in the case that the light-emitting layer 1012 has a multiple quantum well structure, the light-emitting layer 1012 may include potential well layers and potential barrier layers that are alternately arranged. In addition, an area of an orthographic projection of the first conductivity type semiconductor layer 1011 onto the base substrate 100 is larger than an area of an orthographic projection of the light-emitting layer 1012 onto the base substrate 100, and the area of the orthographic projection of the first conductivity type semiconductor layer 1011 onto the base substrate 100 is also larger than an area of an orthographic projection of the second conductivity type semiconductor layer 1013 onto the base substrate 100.

As shown in FIG. 4, the electrode structure 2 may be provided on the light-emitting structure 1. The electrode structure 2 may include an electrode layer 201. The electrode layer 201 may be made of at least one of gold, silver, aluminium, chromium, nickel, platinum, and titanium. There may be two electrode layers 201. One electrode layer 201 may be provided on a surface of the first conductivity type semiconductor layer 1011 facing away from the base substrate 100, and the other electrode layer 201 may be provided on a surface of the second conductivity type semiconductor layer 1013 facing away from the base substrate 100. In other embodiments of the present disclosure, one of the two electrode layers 201 may be provided on the surface of the second conductivity type semiconductor layer 1013 facing away from the base substrate 100, and the other electrode layer 201 may be provided on a surface of the base substrate 100 facing away from the epitaxial structure 101, that is, the light-emitting device is a light-emitting device with a vertical structure. The light-emitting device according to the present disclosure may further include an insulation layer 4. The insulation layer 4 may cover the electrode layer 201, the epitaxial structure 101, and the base substrate 100 as described above. The insulation layer 4 may be provided with an opening exposing the electrode layer 201. There may be two openings that expose the two electrode layers 201 in a one-to-one correspondence.

As shown in FIG. 4, the electrode structure 2 may further include a conductive bridging layer 202 and a barrier layer 203. The conductive bridging layer 202 may cover a surface of the insulation layer 4 facing away from the base substrate 100. The conductive bridging layer 202 may extend into the opening in the insulation layer 4 and contact the electrode layer 201. The conductive bridging layer 202 may have a laminated structure. The laminated structure may be a three-layer laminated structure, which may include two titanium metal layers disposed opposite to each other and an aluminium metal layer disposed between the two titanium metal layers. There may be two conductive bridging layers 202, which may extend into the two openings in the insulation layer 4 in a one-to-one correspondence and contact the two electrode layers 201 in a one-to-one correspondence. The barrier layer 203 may be provided on a surface of the conductive bridging layer 202 facing away from the base substrate 100. The barrier layer 203 may be made of one or more of nickel, platinum, and gold. There may be two barrier layers 203, which are provided on surfaces of the two conductive bridging layers 202 facing away from the base substrate 100 in a one-to-one correspondence. The barrier layer 203 can prevent metal elements (mainly Sn) in the die-bonding structure 3 from being diffused to the electrode layer 201 during a soldering process, and prevent the diffused metal elements from forming an intermetallic compound with the material of the electrode layer 201, thereby preventing abnormal soldering.

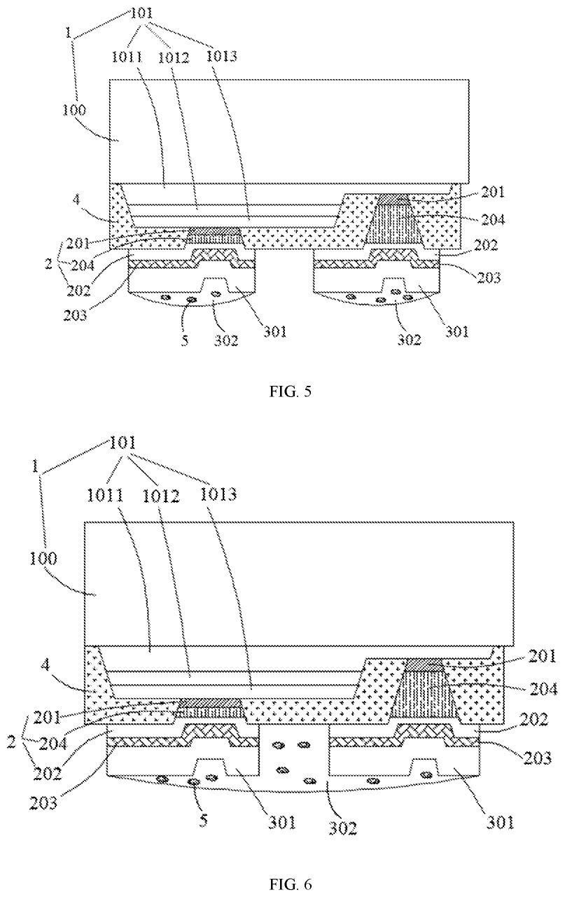

As shown in FIG. 5, in other embodiments of the present disclosure, the electrode structure 2 may further include a conductive filler 204. The conductive filler 204 fills the opening in the insulation layer 4 and is in contact with the electrode layer 201. A surface of the conductive filler 204 facing away from the light-emitting structure 1 may be flush with a surface of the insulation layer 4 facing away from the light-emitting structure 1, that is, the opening in the insulation layer 4 is fully filled with the conductive filler 204, and the conductive filler 204 does not extend out of the opening in the insulation layer 4. However, the surface of the conductive filler 204 facing away from the light-emitting structure 1 may be lower than the surface of the insulation layer 4 facing away from the light-emitting structure 1, that is, the insulation layer 4 is not fully filled with the conductive filler 204. In other words, a distance between the surface of the conductive filler 204 facing away from the light-emitting structure 1 and the base substrate 100 is less than a distance between the surface of the insulation layer 4 facing away from the light-emitting structure 1 and the base substrate 100. There may be two conductive fillers 204, which fill the two openings in the insulation layer 4 in a one-to-one correspondence. The two conductive bridging layers 202 as described above may contact surfaces of the two conductive fillers 204 facing away from the light-emitting structure 1 in a one-to-one correspondence.

As shown in FIG. 4 and FIG. 5, at least a portion of the die-bonding structure 3 covers the surface of the electrode structure 2 facing away from the light-emitting structure 1. For example, in the case that the electrode structure 2 includes the barrier layer 203, the die-bonding structure 3 may cover a surface of the barrier layer 203 facing away from the light-emitting structure 1. The die-bonding structure 3 includes the doping material 5. The doping material 5 serves to suppress the generation of an intermetallic compound.

As shown in FIG. 4 and FIG. 5, the die-bonding structure 3 may include a solder layer 301. The solder layer 301 may cover the surface of the electrode structure 2 facing away from the light-emitting structure 1. For example, the solder layer 301 covers the surface of the barrier layer 203 facing away from the light-emitting structure 1. A solder in the solder layer 301 is tin, tin-silver alloy, tin-silver-copper alloy, indium-tin alloy, or tin-copper alloy, which is not particularly limited in the embodiments of the present disclosure. There may be two solder layers 301, which may cover surfaces of the two barrier layers 203 facing away from the light-emitting structure 1 in a one-to-one correspondence. In addition, a thickness of the solder layer 301 may be 5 μm to 50 μm, for example, 5 μm, 10 μm, 25 μm, 45 μm, 50 μm, etc. An area of an orthographic projection of the electrode layer 201 onto the base substrate 100 is less than an area of an orthographic projection of the solder layer 301 onto the base substrate 100; however, the area of the orthographic projection of the electrode layer 201 onto the base substrate 100 may be equal to the area of the orthographic projection of the solder layer 301 onto the base substrate 100, and the present disclosure is not limited thereto. The area of the orthographic projection of the electrode layer 201 onto the base substrate 100 may be larger than the area of the orthographic projection of the solder layer 301 onto the base substrate 100.

However, as shown in FIG. 5, the die-bonding structure 3 may further include a liquid film 302. The liquid film 302 may cover the solder layer 301. The material of the liquid film 302 may include a soldering flux. The soldering flux may be an organic solvent. The soldering flux has functions of assisting heat conduction, reducing the surface tension of the material to be soldered, removing oil stains from the surface of the material to be soldered, increasing the soldering area, preventing re-oxidation, and the like. In an embodiment of the present disclosure, as shown in FIG. 5, there may be two liquid films 302, which may be arranged at intervals, and cover the two solder layers 301 in a one-to-one correspondence. In other embodiments of the present disclosure, as shown in FIG. 6, there is one liquid film 302, which simultaneously covers the two solder layers 301. The liquid film 302 covering the solder may also cover the surface of the insulation layer 4 facing away from the light-emitting structure 1. The liquid film 302 as described above may be formed by dipping or printing.

As shown in FIG. 4, the doping material 5 serves to suppress the generation of an intermetallic compound. In particular, the doping material 5 serves to suppress the excessive generation of an intermetallic compound, for example, from the scallop shape shown in FIG. 9 to the ridge shape shown in FIG. 10 or the prism shape shown in FIG. 11. The doping material 5 may be doped in the solder layer 301. The doping material 5 doped in the solder layer 301 may be nickel, ferric oxide (Fe₂O₃), silicon dioxide, titanium dioxide, or zirconium dioxide, which is not particularly limited in the embodiments of the present disclosure. The solder layer 301 having the doping material 5 may be formed by evaporation, sputtering, electroplating, or printing, but the present disclosure is not limited thereto. In addition, as shown in FIG. 5, the doping material 5 may also be doped in the liquid film 302. As shown in FIG. 5, in the case that there are two liquid films 302 arranged at intervals, for example, the doping material 5 may be nickel, ferric oxide, silicon dioxide, titanium dioxide, or zirconium dioxide. As shown in FIG. 6, in the case that there is one liquid film 302, for example, the doping material 5 may be an insulating material, such as ferric oxide, silicon dioxide, titanium dioxide, or zirconium dioxide. In other embodiments of the present disclosure, both the solder layer 301 and the liquid film 302 may be provided with the doping material 5 as described above.

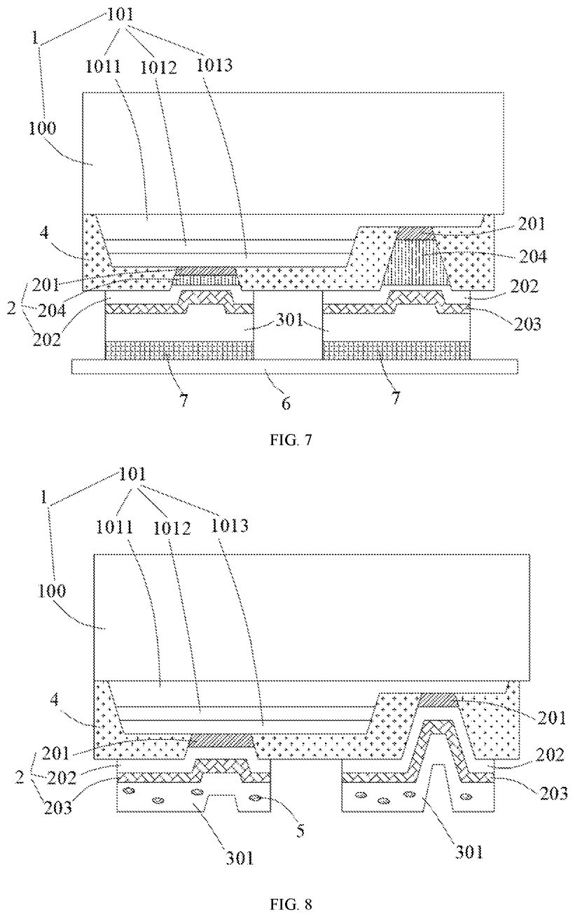

Embodiments of the present disclosure further provide a light-emitting module. As shown in FIG. 7, the light-emitting module may include a substrate 6 and the light-emitting device according to any one of the above embodiments. The substrate 6 is provided with pads 7. The light-emitting device is soldered to the pads 7 on the substrate 6 through the die-bonding structure 3. The light-emitting module can be used as a backlight module of a display module; however, the light-emitting module can be used as the display module itself. When the light-emitting module is used as a display module, the substrate 6 is a driving backplane, which may be provided with thin-film transistors distributed in an array, but the present disclosure is not particularly limited thereto.

Embodiments of the present disclosure further provide a preparation method of the light-emitting module. As shown in FIG. 7, the preparation method of the light-emitting module may include: providing a substrate 6, which is provided with at least one group of pads 7; and soldering the light-emitting device according to any one of the above embodiments to the pads 7 on the substrate 6 through the die-bonding structure 3 with a heat soldering process. The heat soldering process may include a hot-pressure soldering process, a reflow soldering process, or a laser soldering process. As shown in FIG. 4 and FIG. 8, the liquid film 302 in the die-bonding structure 3 of the light-emitting device may be formed in real time during the preparation process by coating, dipping, or the like. In addition, in the present disclosure, a soldering flux in which the above-described doping material 5 is added may be applied to the pads 7 on the substrate 6.

The light-emitting device, the light-emitting module, and the preparation method of the light-emitting module according to the embodiments of the present disclosure belong to the same inventive concept, and descriptions of the relevant details and beneficial effects can be referred to each other, and will not be repeated.

The foregoing are merely preferred embodiments of the present disclosure, and are not intended to limit the present disclosure in any form. Although the present disclosure has been disclosed as above with the preferred embodiments, they are not intended to limit the present disclosure. Any person skilled in the art may, without departing from the scope of the technical solutions of the present disclosure, make some changes or modifications to the above disclosed technical contents into equivalent embodiments. However, any simple modifications, equivalent changes and modifications made to the above embodiments according to the technical essence of the present disclosure without departing from the contents of the technical solutions of the present disclosure still fall within the scope of the technical solutions of the present disclosure.

1. A light-emitting device, comprising:
a light-emitting structure;
an electrode structure provided on the light-emitting structure; and
a die-bonding structure, at least a portion of which covers a surface of the electrode structure facing away from the light-emitting structure, wherein the die-bonding structure comprises a doping material for inhibiting generation of an intermetallic compound.

2. The light-emitting device according to claim 1, wherein the die-bonding structure comprises:
a solder layer covering the surface of the electrode structure facing away from the light-emitting structure, the doping material being doped in the solder layer.

3. The light-emitting device according to claim 2, wherein the doping material comprises at least one of nickel, ferric oxide, silicon dioxide, titanium dioxide, or zirconium dioxide.

4. The light-emitting device according to claim 2, wherein a solder in the solder layer comprises at least one of tin, tin-silver alloy, tin-silver-copper alloy, indium-tin alloy, or tin-copper alloy.

5. The light-emitting device according to claim 1, wherein the electrode structure comprises:
an electrode layer provided on the light-emitting structure; and
a barrier layer provided on a side of the electrode layer facing away from the light-emitting structure, the barrier layer being made of a conductive material.

6. The light-emitting device according to claim 5, wherein the barrier layer is made of at least one of nickel, platinum, or gold.

7. The light-emitting device according to claim 5, wherein the light-emitting device further comprises an insulation layer covering the electrode layer, the insulation layer being provided with an opening exposing the electrode layer, and
the electrode structure further comprises a conductive bridging layer provided on a surface of the insulation layer facing away from the light-emitting structure, extending into the opening and being in contact with the electrode layer, the barrier layer being provided on a surface of the conductive bridging layer facing away from the light-emitting structure.

8. The light-emitting device according to claim 5, wherein the light-emitting device further comprises an insulation layer covering the electrode layer, the insulation layer being provided with an opening exposing the electrode layer, and
the electrode structure further comprises:
a conductive filler filling the opening and being in contact with the electrode layer; and
a conductive bridging layer provided on a surface of the insulation layer facing away from the light-emitting structure and being in contact with a surface of the conductive filler facing away from the light-emitting structure, the barrier layer being provided on a surface of the conductive bridging layer facing away from the light-emitting structure.

9. The light-emitting device according to claim 8, wherein the surface of the conductive filler facing away from the light-emitting structure is flush with the surface of the insulation layer facing away from the light-emitting structure; or
the surface of the conductive filler facing away from the light-emitting structure is lower than the surface of the insulation layer facing away from the light-emitting structure.

10. The light-emitting device according to claim 1, wherein the die-bonding structure comprises:
a solder layer covering a surface of the electrode structure facing away from the light-emitting structure; and
a liquid film covering the solder layer and made of a soldering flux, the doping material being doped in the liquid film.

11. The light-emitting device according to claim 10, wherein
the electrode structure comprises two electrode structures, the solder layer comprises two solder layers, and the liquid film comprises two liquid films arranged at intervals;
the two solder layers are arranged on surfaces of the two electrode structures in a one-to-one correspondence, and the two liquid films cover the two solder layers in a one-to-one correspondence; and
the doping material comprises at least one of nickel, ferric oxide, silicon dioxide, titanium dioxide, or zirconium dioxide.

12. The light-emitting device according to claim 10, wherein
the electrode structure comprises two electrode structures, the solder layer comprises two solder layers, and the liquid film comprises one liquid film;
the two solder layers are arranged on surfaces of the two electrode structures in a one-to-one correspondence, and the liquid film covers the two solder layers; and
the doping material comprises an insulating material.

13. The light-emitting device according to claim 12, wherein the doping material comprises at least one of silicon dioxide, titanium dioxide, or zirconium dioxide.

14. A light-emitting module, comprising:
a substrate provided with at least one group of pads; and
the light-emitting device according to claim 1, wherein the light-emitting device is soldered to the pads on the substrate through the die-bonding structure.

15. A preparation method of a light-emitting module, comprising:
providing a substrate, which is provided with at least one group of pads; and
soldering the light-emitting device according to claim 1 to the pads on the substrate through the die-bonding structure with a heat soldering process.

16. The preparation method of the light-emitting module according to claim 15, wherein the heat soldering process comprises a hot-pressure soldering process, a reflow soldering process, or a laser soldering process.
